(19) United States
(12) Patent Application Publication
(10) Pub. No.: US 2025/0105136 A1
(43) Pub. Date: Mar. 27, 2025

(54) CAPACITORS FOR USE WITH INTEGRATED CIRCUIT PACKAGES

(71) Applicant: Intel Corporation, Santa Clara, CA (US)

(72) Inventors: Kimin Jun, Portland, OR (US); Adel A. Elsherbini, Chandler, AZ (US); Chia-Ching Lin, Portland, OR (US); Sou-Chi Chang, Portland, OR (US); Thomas Lee Sounart, Chandler, AZ (US); Tushar Kanti Talukdar, Wilsonville, OR (US); Johanna Marie Swan, Scottsdale, AZ (US); Uygar Avci, Portland, OR (US)

(21) Appl. No.: 18/473,887

(22) Filed: Sep. 25, 2023

(51) Int. Cl. H01L 23/522; H01L 23/00; H01L 23/498; H01L 23/528; H01L 23/538; H01L 25/065; H01L 25/16

(52) U.S. Cl. CPC H01L 23/5223; H10D 1/682; H01L 23/49816; H01L 23/5283; H01L 23/5381; H01L 23/5385; H01L 24/16; H01L 24/17; H01L 24/32; H01L 25/0655; H01L 25/16; H01L 2224/16227; H01L 2224/17515; H01L 2224/32265; H01L 2924/1205

(57) ABSTRACT

Capacitors for use with integrated circuit packages are disclosed. An example apparatus includes a semiconductor substrate, a metal layer coupled to the semiconductor substrate, a dielectric layer coupled to the metal layer, the dielectric layer including a capacitor disposed therein, and an interface layer positioned between the metal layer and the dielectric layer, the interface layer in contact with the dielectric layer and in contact with the metal layer.

### FIELD OF THE DISCLOSURE

This disclosure relates generally to integrated circuit packages and, more particularly, to capacitors for use with integrated circuit packages.

### BACKGROUND

Integrated circuit (IC) chips and/or semiconductor dies are routinely connected to larger circuit boards such as motherboards and other types of printed circuit boards (PCBs) via a package substrate. As IC chips and/or dies reduce in size and interconnect densities increase, alternatives to traditional substrate layers are needed to facilitate stable transmission of high frequency data signals between different circuitry and/or increased power delivery.

### BRIEF DESCRIPTION OF THE DRAWINGS

FIG. 1 illustrates an example integrated circuit (IC) package on a printed circuit board (PCB).

FIG. 2 is a cross-sectional view of an example semiconductor die that may be included in the example IC package of FIG. 1.

FIG. 3 is a flowchart representative of an example method to manufacture an example semiconductor die disclosed herein.

FIGS. 4A-4E illustrate different stages in an example process of manufacturing the example semiconductor die of FIG. 2.

FIGS. 5A-5E illustrate different stages in an example process of manufacturing the example semiconductor die of FIG. 5E.

FIGS. 6A-6D illustrate different stages in an example process of manufacturing the example semiconductor die of FIG. 6D.

FIGS. 7A and 7B illustrate a first example capacitor constructed in accordance with examples disclosed herein.

FIGS. 8A and 8B illustrate a second example capacitor constructed in accordance with examples disclosed herein.

FIG. 9 illustrates another example IC package in which examples disclosed herein may be implemented.

FIG. 10 illustrates yet another example IC package in which examples disclosed herein may be implemented.

FIG. 11 is a top view of a wafer including dies that may be included in an IC package constructed in accordance with teachings disclosed herein.

FIG. 12 is a cross-sectional side view of an IC device that may be included in an IC package constructed in accordance with teachings disclosed herein.

FIG. 13 is a cross-sectional side view of an IC device assembly that may include an IC package constructed in accordance with teachings disclosed herein.

FIG. 14 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, the term “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Semiconductor packages often employ transmission lines, such as traces, microstrips, and/or other electrical routing, to transmit signals and/or power between package components. As electronic systems become more complex and electrical interfaces in the electronic systems operate at higher frequencies, dense signal processing areas can cause significant crosstalk between adjacent signal paths in such densely packed spaces. Such crosstalk can reduce the performance of the package. Capacitors may be implemented in semiconductor dies during the back end of the line (BEOL) (e.g., after fabrication of transistors and/or other semiconductor devices during the front end of the line (FEOL)) to increase the power efficiency of the dies (e.g., chips) and the associated IC package(s) containing such dies. However, there are limitations on the temperatures that can be used during BEOL fabrication processes because temperatures above a certain threshold (e.g., less than or equal to 300 Celsius (C)-400 C) can compromise the quality of the semiconductor devices (e.g., transistors and interconnects) fabricated during the FEOL or upstream BEOL (e.g., due to copper diffusion, threshold voltage shift, etc.). The thermal budget limit on capacitor fabrication processes during the BEOL limits the quality of capacitors that can be produced. For example, a metal-insulator-metal (MIM) capacitor fabricated during the BEOL (e.g., with a thermal limit of 400 C or less) will result in a capacitor with the insulator having a dielectric constant (κ) of around 80 or less. By contrast, capacitors fabricated with processes subject to a thermal limit of around 600 C can have insulators with a dielectric constant significantly higher than 80 (e.g., greater than 90 and upwards of 130 (e.g., at least 100, at least 110, at least 120)), thereby resulting in improved capacitance density. Further, capacitors fabricated using processes involving even higher temperatures (e.g., above 600 C) can be associated with much higher dielectric constants (e.g., above 150, above 200, above 250, etc.). The reason for the increased dielectric constant in the above scenarios is due to the different crystal phases for the dielectric material for the capacitor insulator that can only be achieved at the higher temperatures.

Examples disclosed herein enable the fabrication of capacitors at any suitable temperature (e.g., above the BEOL thermal limit) for improved capacitance density. Further, in accordance with teachings disclosed herein, such capacitors may be incorporated into semiconductor dies without compromising components fabricated during the FEOL. Specifically, examples disclosed herein involve the fabrication of capacitors on a separate substrate (e.g., wafer or carrier) to the semiconductor substrate (e.g., silicon wafer) on which the FEOL components are fabricated. Inasmuch as the capacitors are fabricated independent of (e.g., in parallel with) the FEOL components, the temperatures used to fabricate the capacitors will not affect the FEOL components. In some examples, once fabricated, the capacitors are bonded to the separately fabricated semiconductor substrate (processed through the FEOL) during BEOL processing. As such, examples disclosed herein result in monolithic semiconductor dies that include capacitors with relatively high-κ (e.g., above 90) dielectric for improved capacitance.

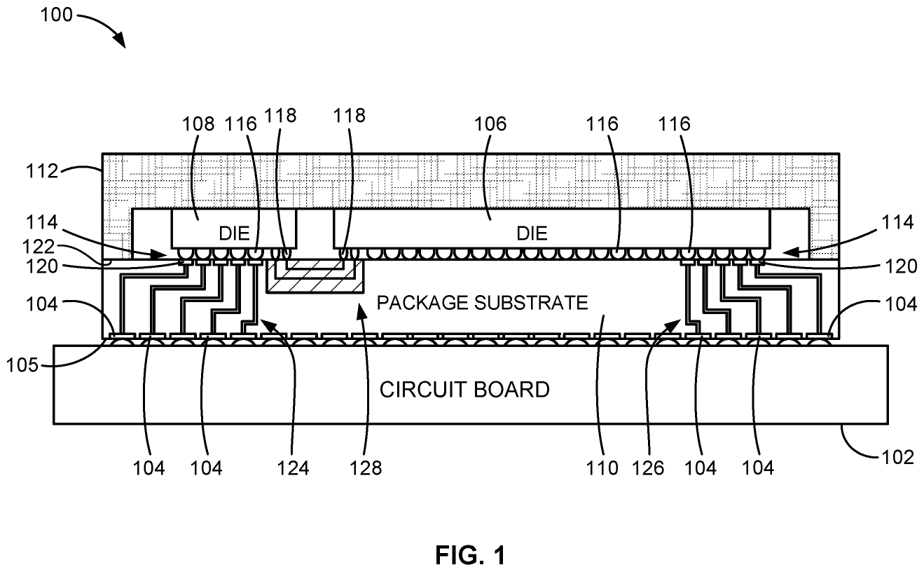

FIG. 1 illustrates an example IC package (e.g., a semiconductor package) 100 constructed in accordance with teachings disclosed herein. In the illustrated example, the IC package 100 is electrically coupled to an example circuit board 102 via an array of example contact pads or lands 104 on an example mounting surface (e.g., a bottom surface) 105 of the package. In some examples, the IC package 100 may include balls, pins, and/or pads, in addition to or instead of the contact pads 104, to enable the electrical coupling of the package 100 to the circuit board 102. In this example, the package 100 includes two example semiconductor (e.g., silicon) dies 106, 108 (sometimes also referred to as chips or chiplets) that are mounted to an example package substrate 110 and enclosed by an example package lid or mold compound 112. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

In the illustrated example, each of the dies 106, 108 is electrically and mechanically coupled to the substrate 110 via corresponding arrays of example interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps, namely, example core bumps 116 and example bridge bumps 118. As used herein, core bumps are bumps on dies through which electrical signals pass between the dies and other components either within an IC package containing the dies (e.g., a different die) or external to the IC package. Thus, as shown in the illustrated example, when the dies 106, 108 are mounted to the package substrate 110, the core bumps 116 are physically connected and electrically coupled to contact pads 120 on an example inner surface 122 of the substrate 110. The contact pads 120 on the inner surface 122 of the package substrate 110 are electrically coupled to the landing pads 104 on the bottom (external) surface 105 of the substrate 110 (e.g., a surface opposite the inner surface 122) via example internal interconnects 124, 126 within the substrate 110. As a result, there is a complete signal path between the bumps 116 of the dies 106, 108 and the landing pads 104 mounted to the circuit board 102 that pass through the contact pads 120 and the interconnects 124, 126 provided therebetween.

As used herein, bridge bumps are bumps on the dies through which electrical signals pass between different ones of the dies within an IC package. More particularly, bridge bumps differ from core bumps in that bridge bumps electrically connect two or more different dies via an interconnect bridge (e.g., the example interconnect bridge 128 of FIG. 1) embedded in an underlying substrate (e.g., the package substrate 110). As represented in FIG. 1, core bumps 116 are typically larger than bridge bumps 118. In some examples, the interconnect bridge 128 and the associated bridge bumps 118 are omitted.

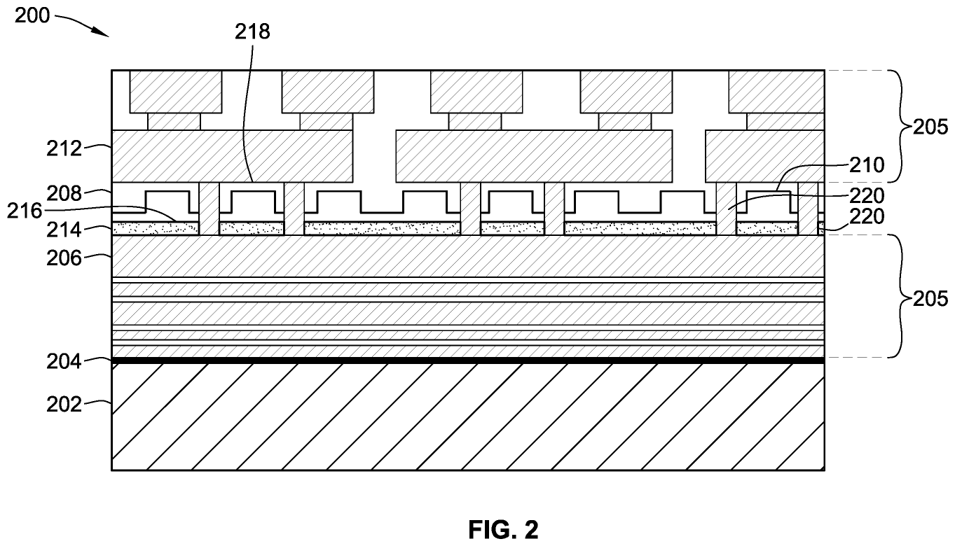

FIG. 2 is a cross-sectional view of an example semiconductor die 200 constructed in accordance with teachings disclosed herein. The example semiconductor die 200 can be implemented as one of the dies 106, 108 in FIG. 1. Alternatively, the example semiconductor die 200 can be included together with the dies 106, 108. The example semiconductor die 200 includes an example semiconductor (e.g., silicon) substrate 202, example transistors 204, and a plurality of metal layers 205 adjacent the transistors 204. As shown in the illustrated example, the different metal layers 205 are separated by intervening layers of dielectric material. In some examples, metal vias (not shown for the sake of simplicity) extend through the intervening layers of dielectric material to electrically interconnect the metal layers 205. The fabrication processes up through the creation of the transistors 204 on the semiconductor substrate 202 (and sometimes an initial metal layer immediately above the transistors 204) constitutes the front end of line (FEOL), whereas all subsequent processing associated with the creation of the rest of the plurality of metal layers 205 constitutes the back end of line (BEOL). In this example, the semiconductor die 200 includes a first example dielectric layer 208 containing a first example capacitor 210 positioned between a first metal layer 206 and a second example metal layer 212. Thus, as shown in the illustrated example, the first capacitor 210 is added during the BEOL, after one or more of the plurality of metal layers 205 (including the first metal layer 206) have been fabricated but before other ones of the metal layers 205 (e.g., the second metal layer 212) have been added. The example semiconductor die 200 also includes an example interface layer 214 adjacent to the first dielectric layer 208 including the first capacitor 210. In particular, the interface layer 214 is in contact with a first example surface 216 of the first dielectric layer 208. The first example surface 216 opposes a second example surface 218 of the first dielectric layer 208. In this example, the semiconductor substrate 202 supports the transistors 204. The example transistors 204 are positioned between the semiconductor substrate 202 and the first metal layer 206.

The first example dielectric layer 208 includes the first capacitor 210 disposed therein. As shown in FIG. 2, the example interface layer (e.g., bonding layer) 214 is positioned between the first metal layer 206 and the first dielectric layer 208. Further, the example interface layer 214 is in contact with the first dielectric layer 208 and in contact with the first metal layer 206. As such, the first dielectric layer 208 is coupled to the first metal layer 206 by way of the interface layer 214. In some examples, the semiconductor die 200 includes example conductive vias 220 that extend through the first dielectric layer 208 and the interface layer 214. The example conductive vias 220 electrically couple the first metal layer 206 to the second example metal layer 212. In this example, the first dielectric layer 208 is positioned between the first metal layer 206 and the second metal layer 212. In some examples, the first dielectric layer 208 can include silicon oxide (SiO₂), silicon oxy-carbide (e.g., SiCO₃), silicon oxy-nitride (e.g., Si₂N₂O), silicon nitride (Si₃N₄), etc. In some examples, the interface layer 214 can include silicon oxide (SiO₂), silicon nitride (Si₃N₄), silicon carbo-nitride (SiCN), silicon oxy-nitride (e.g., Si₂N₂O), etc.

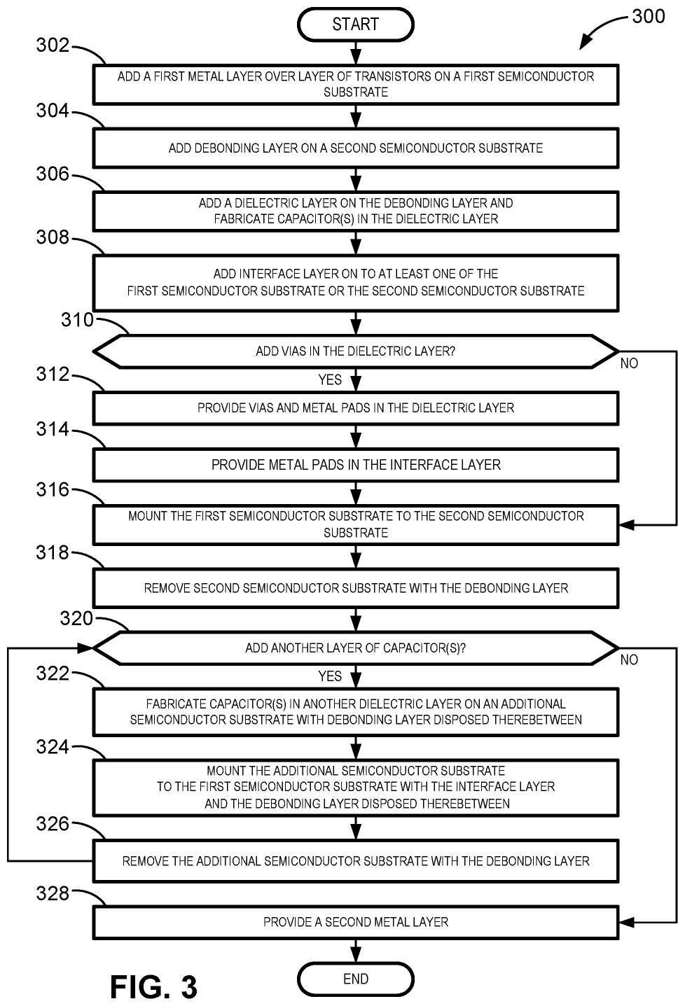

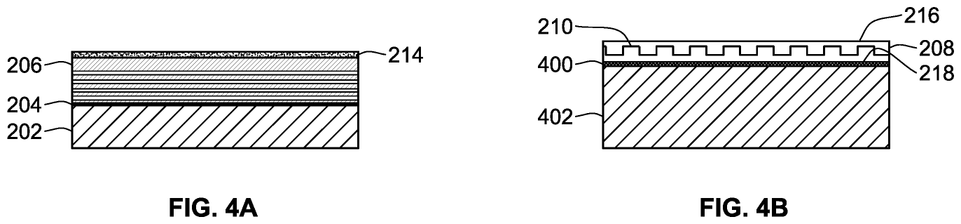

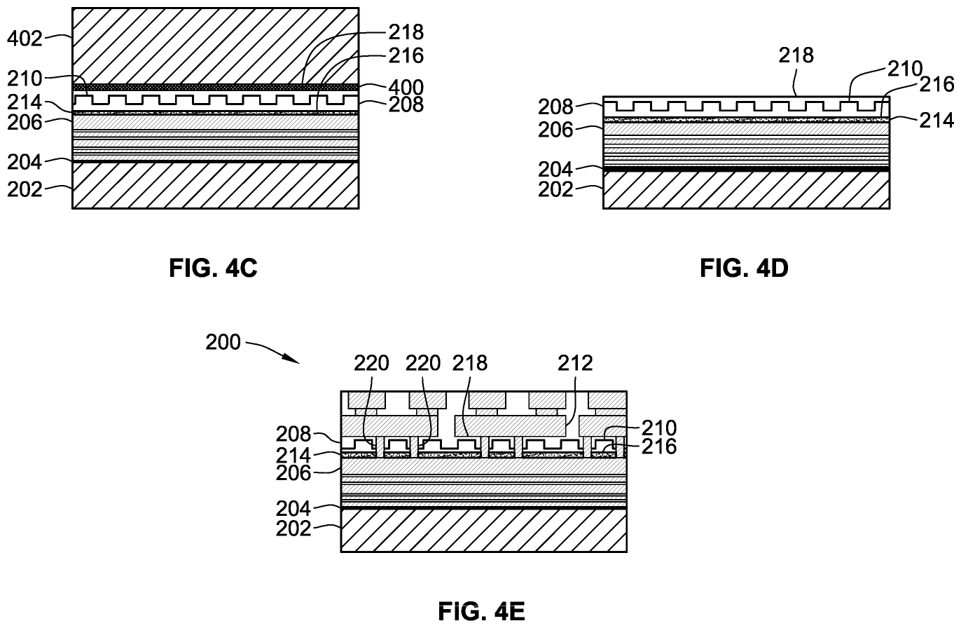

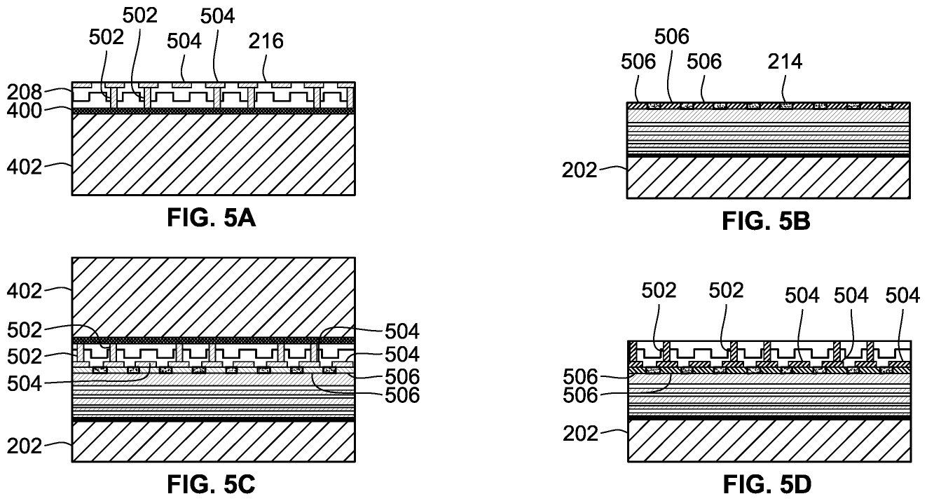

FIG. 3 is a flowchart representative of an example method 300 to produce the example semiconductor die 200 of FIG. 2, an example semiconductor die 500 of FIG. 5E, and an example semiconductor die 600 of FIG. 6D. FIGS. 4A-4E represent the example semiconductor die 200 at various stages during the example process described in FIG. 3. FIGS. 4A, 4B, and 5A-5E represent the example semiconductor die 500 at various stages during the example process described in FIG. 3. FIGS. 4A-4D and 6A-6D represent the example semiconductor die 600 at various stages during the example process described in FIG. 3. In some examples, some or all of the operations outlined in the example method of FIG. 3 are performed automatically by fabrication equipment that is programmed to perform the operations. Although the example method of manufacture is described with reference to the flowchart illustrated in FIG. 3, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

Turning to FIG. 3, the example process begins at block 302 at which a first example metal layer is added (e.g., deposited, positioned, etc.) over an example layer of transistors on a first example semiconductor substrate. In some examples, one or more other metal layers may be added on the transistors prior to the first metal layer. Thus, in this instance, the term “first” in “first example metal layer” is not intended to imply first in time or order but merely to distinguish the first example metal layer from other metal layers. As shown in FIG. 4A, the first example metal layer 206 is added over an example layer of transistors 204 on the first example semiconductor substrate 202. The example transistors 204 are positioned between the first metal layer 206 and the first semiconductor substrate 202. Further, the first example metal layer 206 is coupled to the first semiconductor substrate 202.

At block 304, an example debonding layer is added on a second example semiconductor substrate. As shown in FIG. 4B, a first example debonding layer 400 is added to a second example semiconductor substrate 402. The second example semiconductor substrate 402 is distinct from (e.g., separate from, independent of) the first semiconductor substrate 202. Specifically, in some examples, both the first and second semiconductor substrates 202, 402 correspond to separate semiconductor wafers. Thus, blocks 302, 304 can be done in parallel and/or in reverse order to what is shown in FIG. 3. The first example debonding layer 400 separates the first example dielectric layer 208 from the second semiconductor substrate 402. In some examples, the first debonding layer 400 is a thermally resistive film. In some examples, the first debonding layer 400 includes metals (e.g., titanium nitride) and/or dielectrics (e.g., silicon oxide, silicon nitride, silicon carbide, etc.).

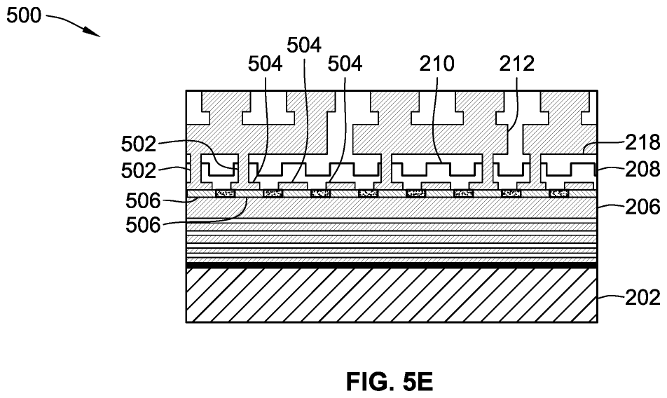

At block 306, an example dielectric layer is added on the debonding layer and example capacitor(s) are fabricated therein. As shown in FIG. 4B, the first example surface 216 of the first dielectric layer 208 opposes the first debonding layer 400. The second example surface 218 of the dielectric layer 208 is in contact with the first debonding layer 400. Further, the first example capacitor 210 is fabricated in the first dielectric layer 208. For purposes of illustration, the first example capacitor 210 is represented by an undulating line extending continuously along the first dielectric layer 208. However, in some examples, the capacitor 210 can have any suitable shape. Specific example structures for the capacitor 210 are described further below in connection with FIGS. 7A-B and 8A-B. In some examples, the capacitor 210 may include electrodes that extend a substantial portion (e.g., a majority, substantially all, or all) across the span (e.g., width) of the first dielectric layer 208 as shown in FIG. 4B. In other examples, the first capacitor 210 is limited to a relatively small and/or discrete portion of the first dielectric layer 208. In some examples, the first dielectric layer 208 includes multiple discrete capacitors 210 distributed along the first dielectric layer 208. Inasmuch as the first and second semiconductor substrates 202, 402 are distinct and independent, block 306 can be done before, after, or in parallel with block 302.

At block 308, an example interface layer is added on to at least one of the first semiconductor substrate or the second semiconductor substrate. As shown in FIG. 4A, the example interface layer 214 is added on the first semiconductor substrate 202. The example interface layer 214 is to enable the attachment or coupling of the first and second semiconductor substrates as discussed further below. Inasmuch as the first and second semiconductor substrates are distinct and independent, if the example interface layer 214 is added onto the first semiconductor substrate 202 (as shown in FIG. 4A), block 308 can be done before, after, or in parallel with blocks 304 and 306. Similarly, if the example interface layer 214 is added onto the second semiconductor substrate 402, block 308 can be done before, after, or in parallel with block 302. In some examples, an example interface layer (e.g., the interface layer 214) is added on the first surface 216 of the first dielectric layer 208.

At block 310, it is determined whether example vias are to be added in the example dielectric layer. Vias may be added to facilitate the electrical coupling of different metal layers on either side of the first dielectric layer 208 once attached to the first semiconductor substrate 202. Further, vias may be added to provide metal pads on the outer surface of the first dielectric layer 208 to facilitate hybrid bonding between the first dielectric layer 208 on the second semiconductor substrate 402 and the first metal layer on the first semiconductor substrate 202 as discussed further below. If example vias are to be added, the process proceeds to block 312 as discussed below in connection with FIGS. 5A-5E. In the example process illustrated by FIGS. 4A-4E, no vias are added. In such examples, the process proceeds to block 316. In the example process illustrated by FIGS. 4A-4E, the process proceeds to block 316.

At block 316, the first example semiconductor substrate is mounted to the second semiconductor substrate. As shown in FIG. 4C, the first semiconductor substrate 202 is mounted (e.g., bonded, attached, coupled, connected, etc.) to the second semiconductor substrate 402 with the interface layer 214 at the interface of the two substrates 202, 402. More particularly, as shown in the illustrated example, the second semiconductor substrate 402 (containing the first dielectric layer 208 and the capacitor 210) is flipped over (relative to the orientation shown in FIG. 4B) and attached to the first semiconductor substrate 202 at the interface layer 214. Thus, in this example, the first metal layer 206 and the first dielectric layer 208 are between the first semiconductor substrate 202 and the second semiconductor substrate 402. Further, a first example surface 216 of the first dielectric layer 208 contacts the interface layer 214. As such, the example interface layer 214 facilitates the mounting (e.g., via fusion bonding, etc.) of the first semiconductor substrate 202 to the second semiconductor substrate 402. In some examples, the first surface 216 of the first dielectric layer 208 is treated (e.g., via planarization and/or plasma activation) to enhance the bondability of the surface. As discussed above, in some examples, the first and second substrates 202, 402 are complete wafers such that the bonding process of block 316 is a wafer-bonding process.

At block 318, the second example semiconductor substrate is removed (e.g., detached) with the debonding layer. As shown in FIG. 4D, the second semiconductor substrate 402 is detached. In particular, the second semiconductor substrate 402, along with the first debonding layer 400, detaches from the first dielectric layer 208. In some examples, the first debonding layer 400 facilitates the detaching of the of the second semiconductor substrate 402 from the first dielectric layer 208. In some examples, the first debonding layer 400 is removed by grinding, chemical-mechanical polishing (CMP), by way of a laser (e.g., infrared laser), wet etch, dry etch, etc.

At block 320, it is determined whether another layer of example capacitor(s) is to be mounted on the first example semiconductor substrate. If another layer of example capacitor(s) is to be added, the process proceeds to block 322 as discussed below in connection with FIGS. 6A-6D. In the example process illustrated by FIGS. 4A-4E, no additional layers of capacitors are added. In such examples, the process proceeds to block 328.

At block 328, a second example metal layer is added. In some examples, more than one additional metal layer is added. That is, in some examples, the BEOL process continues to add additional metal layers until the semiconductor die is completed. As shown in FIG. 4E, the second example metal layer 212 is provided on the second example surface 218 of the first dielectric layer 208. In this example, the second surface 218 opposes the first surface 216 of the first dielectric layer 208. The first example surface 216 faces towards the interface layer 214. In particular, the first example surface 216 is in contact with the interface layer 214. In some examples, as shown in FIG. 4E, one or more of the example vias 220 are provided to extend through the first dielectric layer 208 (e.g., passed and/or through the capacitor 210) before the second metal layer 212 is added. The example vias 220 serve to electrically couple the second metal layer 212 (above the first dielectric layer 208) to the first metal layer 206 (above the first dielectric layer 208). In the example of FIG. 4E, the first semiconductor substrate 202, the first metal layer 206, the first dielectric layer 208, the first capacitor 210 and the interface layer 214 correspond to portions of the semiconductor die 200. That is, while the example process may be performed on full wafers, in some examples, the wafers are cut (e.g., singulated) into individual dies including the semiconductor die 200 shown in FIG. 2.

Returning to block 310, if it is determined that example vias are to be added to the example dielectric layer, the process proceeds to block 312 with the subsequent stages of fabrication represented by FIGS. 5A-5E. At block 312, example vias and metal pads are provided in the example dielectric layer. As shown in FIG. 5A, example vias 502 and first metal pads 504 are provided in the first dielectric layer 208. The example vias 502 extend from the first debonding layer 400 to first example metal pads 504 distributed along the first surface 216 of the first dielectric layer 208.

At block 314, example metal pads are provided in the interface layer. As shown in FIG. 5B, second example metal pads 506 are provided in the interface layer 214. In this example, the second metal pads 506 are spaced apart from one another and exposed along an outer surface of the interface layer 214.

At block 316, the first semiconductor substrate is mounted to the second semiconductor substrate. As shown in FIG. 5C, the first semiconductor substrate 202 is mounted to the second semiconductor substrate 402. In this example, the first metal pads 504 (on the second semiconductor substrate 402) interface with the second metal pads 506 (on the first semiconductor substrate 202) to facilitate the bonding (e.g., hybrid bonding) of the two substrates 202, 402. As such, the first example metal pads 504 contact the second metal pads 506. However, as shown in FIG. 5C, the first and second metal pads 502, 506 may be at least partially offset or misaligned due to misalignments arising from the positioning of the second semiconductor substrate 402 on the first semiconductor substrate 202 when the two substrates are being bonded together (e.g., in a wafer bonding process).

At block 318, the second semiconductor substrate is removed. As shown in FIG. 5D, the second semiconductor substrate 402, along with the first debonding layer 400, is removed. In some examples, the implementation of block 318 in connection with FIGS. 5A-5E is similar or identical to the implementation of block 318 described above in connection with FIGS. 4A-4E. Further, the implementation of blocks 320-328 in connection with FIGS. 5A-5E is similar or identical to the implementation of block 320-328 described above in connection with FIGS. 4A-4E to arrive at the final semiconductor die 500 shown in FIG. 5E.

Returning to block 320, if it is determined another layer of example capacitor(s) is to be added, the process proceeds to block 322 with the subsequent stages of fabrication represented by FIGS. 6A-6D. At block 322, example capacitor(s) are fabricated in another example dielectric layer on an additional semiconductor substrate. As shown in FIG. 6A, a second example capacitor 602 is fabricated in a second example dielectric layer 604 and a third example capacitor 606 is fabricated in a third example dielectric layer 608 on a third example semiconductor substrate 610. Further, a second example debonding layer 612 is disposed between the third semiconductor substrate 610 and the second dielectric layer 604. In the illustrated example of FIG. 6A, the third semiconductor substrate 610 includes two dielectric layers 604, 608. However, in other examples, the third semiconductor substrate 610 may include only one additional dielectric layer 604 (similar to the second semiconductor substrate 402 shown in FIG. 4B). In other examples, the third semiconductor substrate 610 includes more than two additional dielectric layers with associated capacitor(s) provided therein.

At block 324, the additional semiconductor substrate is mounted to the first semiconductor substrate. As shown in FIG. 6B, the third example semiconductor substrate 610 is mounted to the first semiconductor substrate 202 (with the first dielectric layer 208 already attached thereto as shown in FIG. 4D). As shown in the illustrated example, the additional dielectric layers 604, 608 are positioned directly against the first dielectric layer 208 so that all three dielectric layers 208, 604, 608 are positioned together with the associated capacitors 210, 602, 606 similarly grouped together. Thus, the first metal layer 206, the first dielectric layer 208, the second dielectric layer 604, the third dielectric layer 608, the second debonding layer 612, and the interface layer 214 are between the first semiconductor substrate 202 and the third semiconductor substrate 610. The third example dielectric layer 608 is positioned on an opposite side of the first dielectric layer 208 than the interface layer 214. Although the example assembly of FIG. 6B is described as being produced through two separate transfers of the dielectric layers 208, 604, 608 from the second and third semiconductor substrates 402, 610, in other examples, the assembly can be produced in a different number of transfers. For instance, in some examples, all three dielectric layers 208, 604, 608 may be created on the second semiconductor substrate 402 and transferred during a single bonding process. In other examples, each dielectric layer 208, 604, 608 is transferred in a separate bonding process (from each of three separate semiconductor substrates). Additionally or alternatively, an example interface layer (e.g., the interface layer 214) is added on the second surface 218 of the first dielectric layer 208 to facilitate bonding between the first dielectric layer 208 and the second dielectric layer 604. In other examples, an interface layer is added on a surface of the second dielectric layer 604 to facilitate bonding between the first dielectric layer 208 and the second dielectric layer 604. Further, an example interface layer can be added on a surface of the second dielectric layer 604 or a surface of the third dielectric layer 608 to facilitate bonding between the second dielectric layer 604 and the third dielectric layer 608.

At block 326, the third semiconductor substrate is removed. As shown in FIG. 6C, the third semiconductor substrate 610, along with the second debonding layer 612, is removed. Thereafter, the process returns to block 320 to determine whether additional layers of capacitor(s) are to be added. If so, the process again proceeds through blocks 322-326. Otherwise, the example process proceeds to block 328.

At block 328, a second example metal layer is added. As shown in FIG. 6D, the second example metal layer 212 is provided on a third example surface 614 of the second dielectric layer 604. In some examples, the implementation of block 328 in connection with FIGS. 6A-6D is similar or identical to the implementation of block 328 described above in connection with FIGS. 4A-4E. In connection with FIGS. 6A-6D, the third surface 614 opposes the first surface 216 of the first dielectric layer 208. In some examples, the second metal layer 212 is electrically coupled to the first metal layer 206 through the vias 220. In the example of FIG. 6D, the first semiconductor substrate 202, the first metal layer 206, the interface layer 214, the first dielectric layer 208, the second dielectric layer 604, the third dielectric layer 608, the capacitors 210, 602, 606, and the second metal layer 212 correspond to portions of the example semiconductor die 600. Then, the process ends.

FIGS. 7A and 7B illustrate an example capacitor 700 that may be implemented as any of the capacitors 210, 602, 606. The example capacitor 700 is an example metal-insulator-metal (MIM) capacitor that includes a first example electrode 702 and a second example electrode 704 separated by a dielectric material 706. In some examples, the first example electrode 702 and/or the second example electrode 704 may be implemented as a metal plate, a metal layer, etc. In some examples, the capacitor 700 may be referred to as or a planar capacitor because the electrodes generally lie in the same plane as the first dielectric layer 208 containing the capacitor 700 (e.g., a plane defined by either one of the first or second surfaces 216, 218 of the first dielectric layer 208). In some examples, the capacitor 700 may exhibit a stepped profile (e.g., stepped pattern) in which one of the electrodes (e.g., the first electrode 702) follows and/or defines a step around an end or edge of the other electrode (e.g., the second electrode 704).

Turning to FIG. 7A, the example capacitor 700 is embedded in the first dielectric layer 208 (FIG. 4B). In FIG. 7A, the example capacitor 700 is shown in an orientation at time of manufacture of the capacitor 700 on the second semiconductor substrate 402 prior to being flipped over and transferred to the first semiconductor substrate 202. That is, the second example semiconductor substrate 402, the first debonding layer 400, and the capacitor 700 are positioned in a first orientation as shown in FIG. 7A.

In FIG. 7B, the second semiconductor substrate 402 is mounted to the first semiconductor substrate 202. The example capacitor 700, the first dielectric layer 208, the interface layer 214, and the first debonding layer 400 are positioned between the first semiconductor substrate 202 and the second semiconductor substrate 402. The example capacitor 700 is positioned in a second orientation (e.g., upside down, inverted, etc.) different than the first orientation. The example capacitor 700 includes a first example portion 708 of the first electrode 702 that extends adjacent to the first surface 216 of the first dielectric layer 208 and a second portion 710 of the first electrode 702 that extends towards the second surface 218 of the first dielectric layer 208. Further, the first portion 708 of the first electrode 702 is closer to the interface layer 214 than the second electrode 704 is to the interface layer 214. In some examples, the second electrode 704 and the first portion 708 of the first electrode 702 are substantially parallel (e.g., within 5 degrees) to the first surface 216.

As shown in FIG. 7B, a third example portion 712 of the first example electrode 702 is coplanar with the second electrode 704. The third example portion 712 of the first electrode 702 is separated from a first surface 714 (e.g., an edge or end) of the second electrode 704 by a first example segment 716 of the dielectric material 706. Additionally, a second example segment 718 of the dielectric material 706 extends along a second example surface 720 of the second electrode 704. The second example segment 718 separates the second surface 720 of the second electrode 704 from the first portion 708 of the first electrode 702. Further, the second example surface 720 faces toward the interface layer 214.

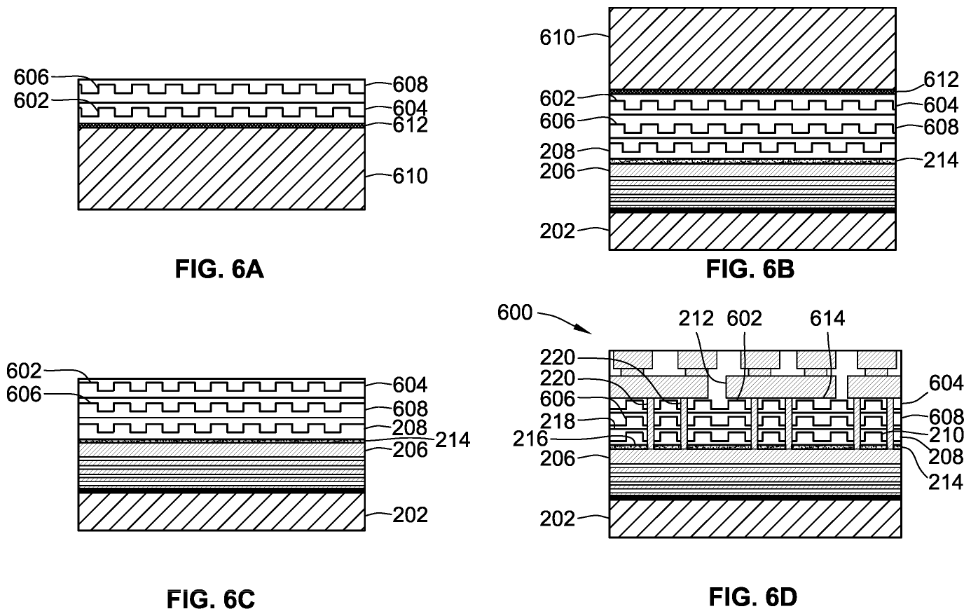

FIGS. 8A and 8B illustrate an example capacitor 800 that may be implemented as any of the capacitors 210, 602, 606. The example capacitor 800 is another example MIM capacitor that includes a first example electrode 802 and a second example electrode 804 separated by a dielectric material 806. In some examples, the first electrode 802 and/or the second electrode 804 may be implemented as a metal plate, a metal layer, etc. In some examples, the capacitor 800 may be referred to as a trench capacitor because the electrodes 802, 804 (and the dielectric material 806 therebetween) extend into a trench that extends in a direction normal to the plane of the first dielectric layer 208 (e.g., a plane defined by either of the first or second surfaces 216, 218 of the first dielectric layer 208).

Turning to FIG. 8A, the example capacitor 800 is embedded in the first dielectric layer 208 (FIG. 4B). In FIG. 8A, the example capacitor 800 is shown in an orientation at time of manufacture of the capacitor 800 on the second semiconductor substrate 402 prior to being flipped over and transferred to the first semiconductor substrate 202. That is, the second example semiconductor substrate 402, the first debonding layer 400, and the capacitor 800 are positioned in a first orientation as shown in FIG. 8A.

In FIG. 8B, the second semiconductor substrate 402 is mounted to the first semiconductor substrate 202. The example capacitor 800, the first dielectric layer 208, the interface layer 214, and the first debonding layer 400 are positioned between the first semiconductor substrate 202 and the second semiconductor substrate 402. The example capacitor 800 is positioned in a second orientation different than the first orientation. The first and second example electrodes 802, 804 extend into a trench (e.g., cavity) in the first dielectric layer 208. In this example, the trench extends between the first surface 216 and the second surface 218. Further, the example trench includes a tapered profile with a first width proximate to the first surface 216 and a second width proximate to the second surface 218, the first width greater than the second width. In other words, a distance between side walls of the trench reduces along the trench in a direction away from the interface layer 214.

The first example electrode 802 includes a first example terminal (e.g., node, lead, etc.) 808 and the second electrode 804 includes a second example terminal 810. The first example terminal 808 and the second terminal 810 are closer to the first surface 216 than the terminals 808, 810 are to the second surface 218 of the first dielectric layer 208.

In FIGS. 7A, 7B, 8A, and 8B, the example dielectric material 706 and/or the example dielectric material 806 is a relatively high-κ dielectric. In some examples, the dielectric material 706, 806 is fabricated using temperatures above the BEOL thermal limit (e.g., above 400 C, above 450 C, above 500 C, above 600 C, etc.) to achieve crystal structures associated with dielectric constants greater than 90 (e.g., at least 95, at least 100, at least 120, at least 150, at least 200, at least 250, etc.). More particularly, the dielectric material 706, 806 may include at least one of a perovskite crystal structure (e.g., Barium titanate (BaTiO₃), Strontium Titanate (SrTiO₃), or Bismuth ferrite (BiFeO₃), etc. with one or more of a Lanthanum (La) dopant, a Hydrogen fluoride (HF) dopant, a Zirconium (Zr) dopant, etc.) or a fluorite crystal structure (e.g., Hafnium (IV) oxide (HfO₂), Zirconium dioxide (ZrO₂), Titanium dioxide (TiO₂), Lanthanum (III) oxide (La₂O₃), Tantalum pentoxide (Ta₂O₅), etc.). Further, the example dielectric materials 706, 806 may include at least one of Titanium oxide, Strontium oxide, Hafnium oxide, or Zirconium oxide. In some examples, the electrodes 702, 704, 802, 804 can include metal (Titanium (Ti), Titanium nitride (TiN), Ruthenium, Tantalum (Ta), Tantalum nitride (TaN), Iridium (Ir), Platinum (Pt), Niobium (Nb), Niobium nitride (NbN), Tungsten (W), Hafnium (Hf), Zirconium (Zr), etc.) or metal oxide (e.g., Ruthenium (IV) oxide (RuO₂), Iridium dioxide (IrO₂), Niobium (V) oxide (Nb₂O₅), etc.).

In FIGS. 7A and 7B, as well as in FIGS. 8A and 8B, two discrete capacitors are shown. In other examples, only one capacitor is implemented. In other examples, more than two capacitors may be implemented. In some examples, the different capacitors are electrical coupled together to function as one larger capacitor and/or a capacitor bank. In some examples, both the planar capacitor 700 (of FIGS. 7A and 7B) and the trench capacitor 800 (of FIGS. 8A and 8B) may be implemented in the same semiconductor die and/or the same dielectric layer.

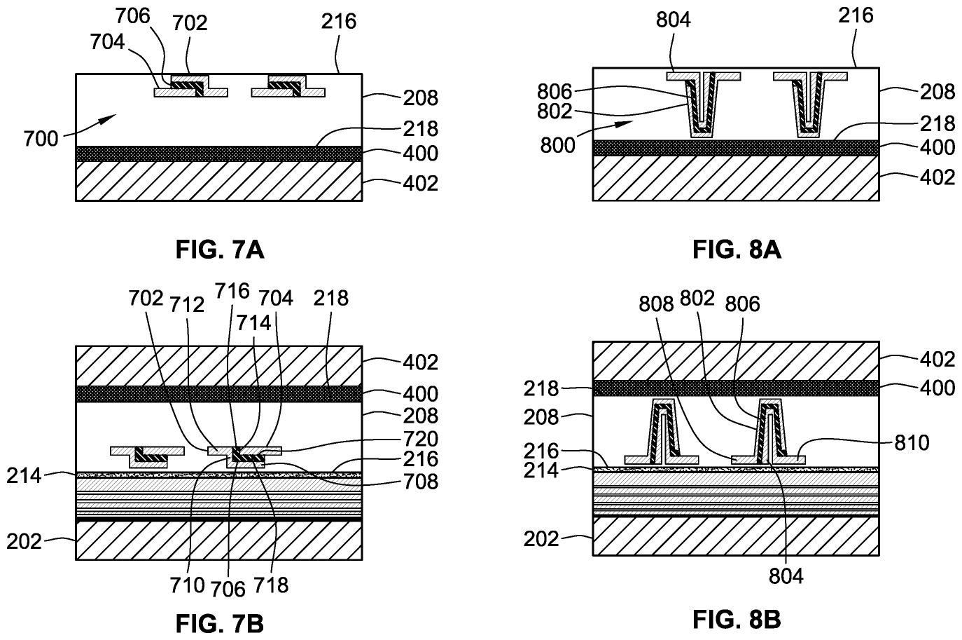

FIG. 9 is an example IC package 900 in which examples disclosed herein can be implemented. The example IC package 900 includes an example package substrate 902, example semiconductor dies 904, 906, 908, 910, 912, 914, 916, and an example capacitor 918. The example package substrate 902 supports the semiconductor dies 904, 906, 908, 910, 912, 914, 916. The example capacitor 918 may be similar to any of the example capacitors 210, 602, 606, 700, 800 described above in connection with FIGS. 2-8B. The example capacitor 918 is positioned in an example dielectric layer 920 positioned between the semiconductor dies 904, 906, 908, 910 and the package substrate 902, while the other semiconductor dies 912, 914, 916 are positioned between the dielectric layer 920 (containing the capacitor 918) and the package substrate 902. As shown in the illustrated example, the dielectric layer 920 is external to and wider than (e.g., extends beyond lateral sides) of each of the semiconductor dies 904, 906, 908, 910, 912, 914, 916. In this example, the dielectric layer 920 (and the associated capacitor 918) are not embedded within any one of the dies 904, 906, 908, 910, 912, 914, 916 as part of a monolithic die. Rather, each of the dies 904, 906, 908, 910, 912, 914, 916 may be independently fabricated to completion and then assembled to produce the example IC package 900 of FIG. 9. In such examples, the package is assembled up to everything shown in FIG. 9 below the interface layer 922. In parallel with this, the capacitor 918 is fabricated on a separate substrate (similar to what is shown and described above in connection with FIG. 4B) and then transferred to the assembly in a similar manner discussed above in connection with FIGS. 4C and 4D. In some examples, the processes described in connection with FIGS. 5A-5E and/or 6A-6D may additionally or alternatively be implemented in connection with FIG. 9. Further, in some examples, any one of the dies 904, 906, 908, 910, 912, 914, 916 may include capacitors constructed in accordance with what is shown and described above in connection with FIGS. 2-6D.

In the example of FIG. 9, an example interface layer 922 separates the dielectric layer 920 from an example metal layer 924. In this example, the metal layer 924 is positioned between the die 910 and the package substrate 902 and, more particularly, between the die 912, and the die 914. In other examples, the metal layer 924 may correspond to a metal layer within one of the dies 912, 914. Further, the example metal layer 924 is electrically coupled to the package substrate 902 through the die 914 and example bumps 926. In some examples, the metal layer 924 may be positioned anywhere between the interface layer 922 and the package substrate 902.

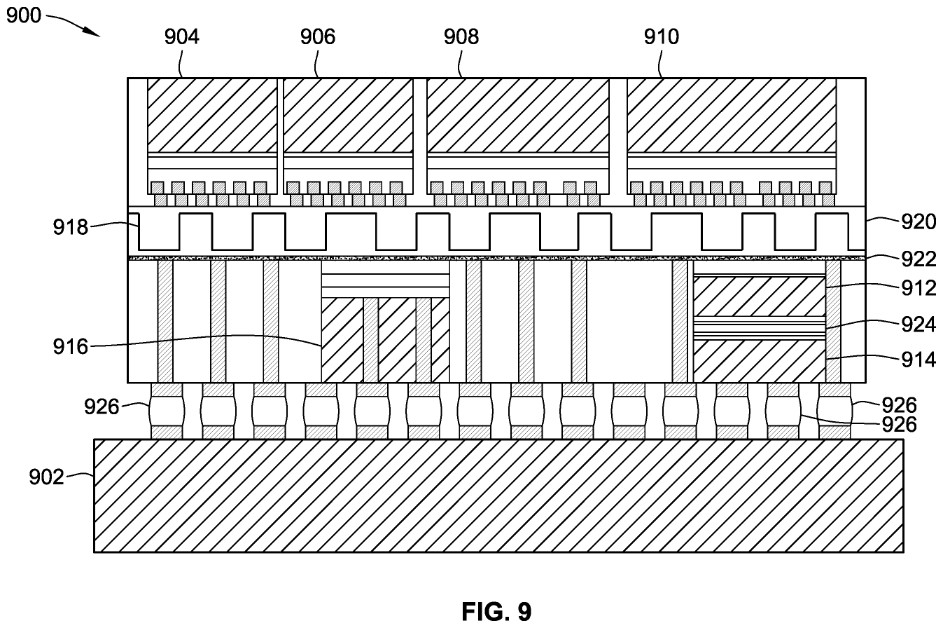

FIG. 10 is an example IC package 1000 in which examples disclosed herein can be implemented. The example IC package 1000 includes first and second example semiconductor dies 1002, 1003, an example package substrate 1004, an example dielectric layer 1006, and an example assembly 1008. The example package substrate 1004 supports the semiconductor die 1002. Further, the example dielectric layer 1006 is positioned between the semiconductor die 1002 and the package substrate 1004. Additionally, first example vias 1010 extend through the dielectric layer 1006 to electrically couple the package substrate 1004 to the semiconductor dies 1002, 1003. In this example, the example assembly 1008 of FIG. 10 is a semiconductor die similar to the example semiconductor package 200 shown in FIG. 4E. However, the example assembly 1008 of FIG. 10 includes second example through silicon vias 1012 extending through the first semiconductor substrate 202. The second example through silicon vias 1012 enable the transistors 204 to be electrically coupled to the package substrate 1004 through the backside (bottom in FIG. 10) of the assembly 1008 in addition to being electrically coupled to the semiconductor dies 1002, 1003 through the front side (top in FIG. 10) of the assembly 1008. In some examples, any one of the examples described in connection with FIG. 5E or 6D may additionally or alternatively be implemented in the example IC package 1000 of FIG. 10.

The foregoing examples of the capacitors 210, 602, 606, 700, 800 within any one of the example semiconductor dies 200, 500, 600 and/or IC packages 100, 900, 1000 teach or suggest different features. Although each example capacitors 210, 602, 606, 700, 800 and the associated example semiconductor dies 200, 500, 600, 1008 and/or IC packages 100, 900, 1000 disclosed above has certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features.

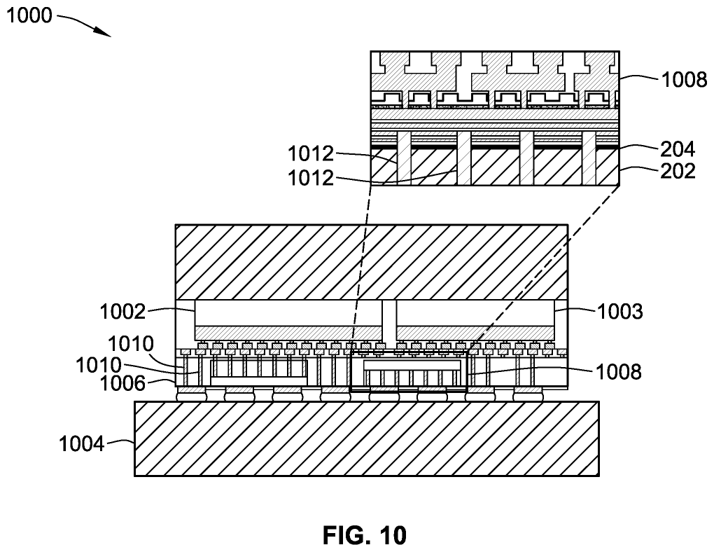

The example IC packages 100, 900, 1000 and/or the example semiconductor dies 200, 500, 600, 1008 disclosed herein may be included in any suitable electronic component. FIGS. 11-14 illustrate various examples of apparatus that may include or be included in the IC packages 100, 900, 1000 and/or the example semiconductor dies 200, 500, 600, 1008 disclosed herein.

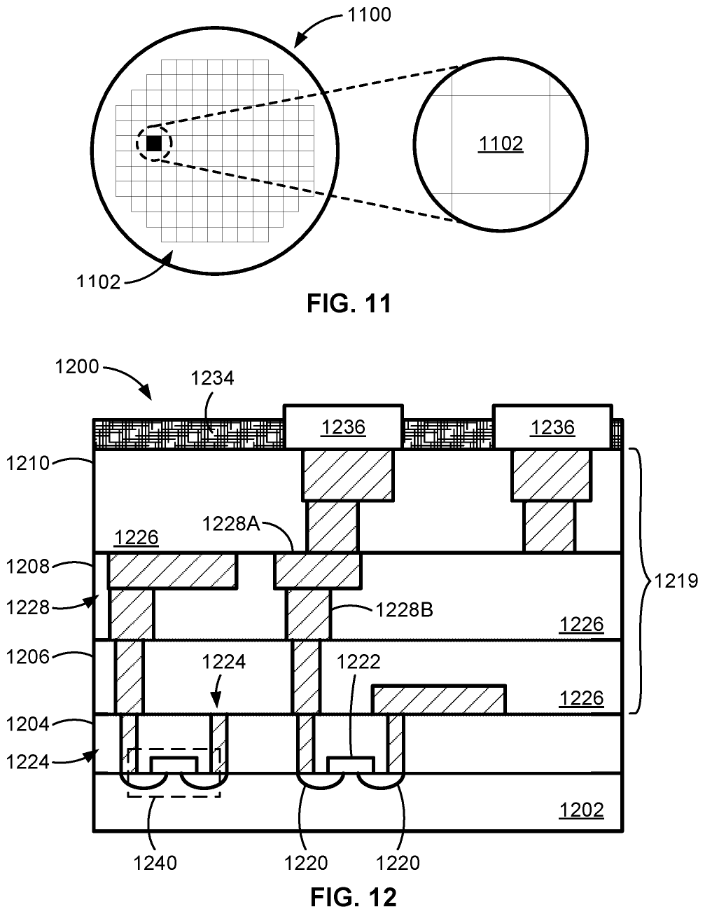

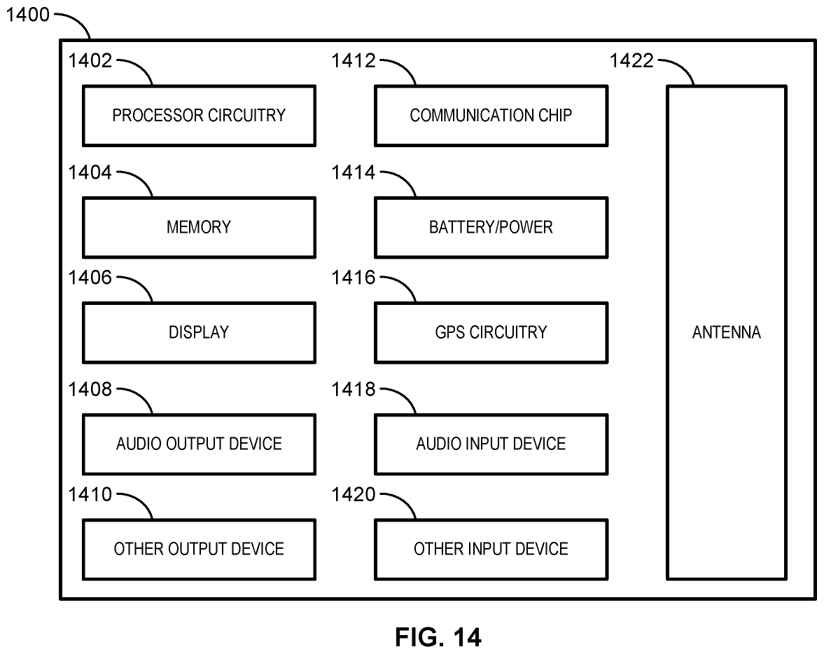

FIG. 11 is a top view of an example wafer 1100 and dies 1102 that may be included in the IC packages 100, 900, 1000 (e.g., as any suitable ones of the dies 106, 108, 200, 500, 600). The wafer 1100 may be composed of semiconductor material and may include one or more dies 1102 having circuitry. Some or all of the dies 1102 may be a repeating unit of a semiconductor product. After the fabrication of the semiconductor product is complete, the wafer 1100 may undergo a singulation process in which the dies 1102 are separated from one another to provide discrete “chips.” The die 1102 may include one or more transistors (e.g., some of the transistors 1240 of FIG. 12, discussed below), supporting circuitry to route electrical signals to the transistors, passive components (e.g., traces, resistors, capacitors, inductors, and/or other circuitry), and/or any other components. In some examples, the die 1102 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 1102. For example, a memory array formed by multiple memory circuits may be formed on a same die 1102 as programmable circuitry (e.g., the processor circuitry 1402 of FIG. 14) or other logic circuitry. Such memory may store information for use by the programmable circuitry. The example IC packages 100, 900, 1000 disclosed herein may be manufactured using a die-to-wafer assembly technique in which some dies 106, 108, 200, 500, 600 are attached to a wafer 1100 that include others of the dies 106, 108, 200, 500, 600, and the wafer 1100 is subsequently singulated.

FIG. 12 is a cross-sectional side view of an example IC device 1200 that may be included in the example IC packages 100, 900, 1000 (e.g., in any one of the dies 106, 108, 200, 500, 600). One or more of the IC devices 1200 may be included in one or more dies 1102 (FIG. 11). The IC device 1200 may be formed on an example die substrate 1202 (e.g., the wafer 1100 of FIG. 11) and may be included in a die (e.g., the die 1102 of FIG. 11). The die substrate 1202 may be a semiconductor substrate composed of semiconductor material systems including, for example, n-type or p-type materials systems (or a combination of both). The die substrate 1202 may include, for example, a crystalline substrate formed using a bulk silicon or a silicon-on-insulator (SOI) substructure. In some examples, the die substrate 1202 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an IC device 1200 may be used. The die substrate 1202 may be part of a singulated die (e.g., the dies 1102 of FIG. 11) or a wafer (e.g., the wafer 1100 of FIG. 11).

The IC device 1200 may include one or more example device layers 1204 disposed on or above the die substrate 1202. The device layer 1204 may include features of one or more example transistors 1240 (e.g., metal oxide semiconductor field-effect transistors (MOSFETs)) formed on the die substrate 1202. The device layer 1204 may include, for example, one or more example source and/or drain (S/D) regions 1220, an example gate 1222 to control current flow between the S/D regions 1220, and one or more example S/D contacts 1224 to route electrical signals to/from the S/D regions 1220. The transistors 1240 may include additional features not depicted for the sake of clarity such as, for example, device isolation regions, gate contacts, and the like. The transistors 1240 are not limited to the type and configuration depicted in FIG. 12 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 1240 may include an example gate 1222 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as for example a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1240 along the source-channel-drain direction, the gate electrode may include a U-shaped structure that includes a bottom portion substantially parallel to the surface of the die substrate 1202 and two sidewall portions that are substantially perpendicular to the top surface of the die substrate 1202. In other examples, at least one of the metal layers that form the gate electrode may be a planar layer that is substantially parallel to the top surface of the die substrate 1202 and does not include sidewall portions substantially perpendicular to the top surface of the die substrate 1202. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of respective ones of the transistors 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes the dopants to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1220 may be formed using one or more alternate semiconductor materials such as germanium or a group III-V material or alloy. In further examples, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more example interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with example interconnect structures 1228 of the interconnect layers 1206-1210. The one or more interconnect layers 1206-1210 may form an example metallization stack (also referred to as an “ILD stack”) 1219 of the IC device 1200.

The interconnect structures 1228 may be arranged within the interconnect layers 1206-1210 to route electrical signals according to a wide variety of designs (in particular, the arrangement is not limited to the particular configuration of interconnect structures 1228 depicted in FIG. 12). Although a particular number of interconnect layers 1206-1210 is depicted in FIG. 12, examples of the present disclosure include IC devices having more or fewer interconnect layers than depicted.

In some examples, the interconnect structures 1228 may include example lines 1228a and/or example vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page from the perspective of FIG. 12. The vias 1228b may be arranged to route electrical signals in a direction of a plane that is substantially perpendicular to the surface of the die substrate 1202 upon which the device layer 1204 is formed. In some examples, the vias 1228b may electrically couple lines 1228a of different interconnect layers 1206-1210 together.

The interconnect layers 1206-1210 may include an example dielectric material 1226 disposed between the interconnect structures 1228, as shown in FIG. 12. In some examples, the dielectric material 1226 disposed between the interconnect structures 1228 in different ones of the interconnect layers 1206-1210 may have different compositions. In other examples, the composition of the dielectric material 1226 between different interconnect layers 1206-1210 may be the same.

A first interconnect layer 1206 (referred to as Metal 1 or “M1”) may be formed directly on the device layer 1204. In some examples, the first interconnect layer 1206 may include lines 1228a and/or vias 1228b, as shown. The lines 1228a of the first interconnect layer 1206 may be coupled with contacts (e.g., the S/D contacts 1224) of the device layer 1204.

A second interconnect layer 1208 (referred to as Metal 2 or “M2”) may be formed directly on the first interconnect layer 1206. In some examples, the second interconnect layer 1208 may include vias 1228b to couple the lines 1228a of the second interconnect layer 1208 with the lines 1228a of the first interconnect layer 1206. Although the lines 1228a and the vias 1228b are structurally delineated with a line within each interconnect layer (e.g., within the second interconnect layer 1208) for the sake of clarity, the lines 1228a and the vias 1228b may be structurally and/or materially contiguous (e.g., simultaneously filled during a dual-damascene process) in some examples.

A third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 and/or the first interconnect layer 1206. In some examples, the interconnect layers that are “higher up” in the metallization stack 1219 in the IC device 1200 (i.e., further away from the device layer 1204) may be thicker.

The IC device 1200 may include an example solder resist material 1234 (e.g., polyimide or similar material) and one or more example conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to other external devices. For example, solder bonds may be formed on the one or more conductive contacts 1236 to mechanically and/or electrically couple a chip including the IC device 1200 with another component (e.g., a circuit board). The IC device 1200 may include additional or alternate structures to route the electrical signals from the interconnect layers 1206-1210; for example, the conductive contacts 1236 may include other analogous features (e.g., posts) that route the electrical signals to external components.

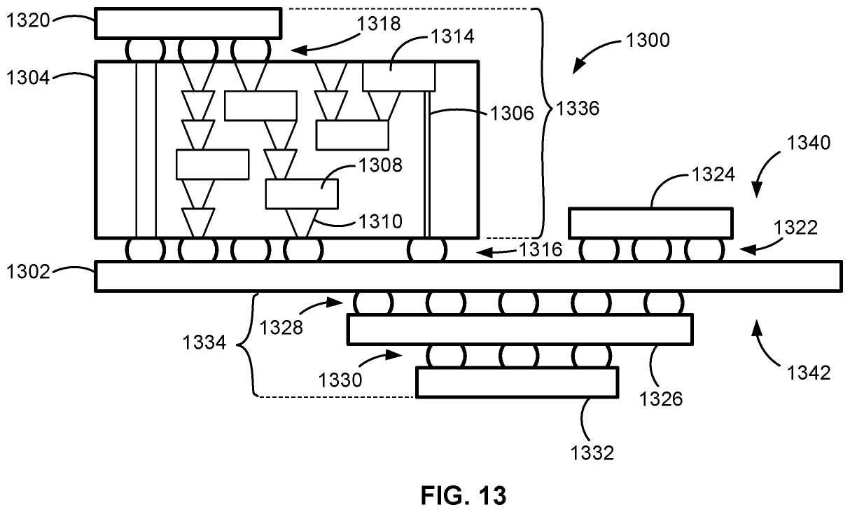

FIG. 13 is a cross-sectional side view of an example IC device assembly 1300 that may include the IC packages 100, 900, 1000 disclosed herein. In some examples, the IC device assembly corresponds to the IC packages 100, 900, 1000. The IC device assembly 1300 includes a number of components disposed on an example circuit board 1302 (which may be, for example, a motherboard). The IC device assembly 1300 includes components disposed on an example first face 1340 of the circuit board 1302 and an example opposing second face 1342 of the circuit board 1302. Any of the IC packages discussed herein with reference to the IC device assembly 1300 may take the form of the example IC packages 100, 900, 1000.

In some examples, the circuit board 1302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1302. In other examples, the circuit board 1302 may be a non-PCB substrate. In some examples, the circuit board 1302 may be, for example, the circuit board 102 of FIG. 1.

The IC device assembly 1300 illustrated in FIG. 13 includes an example package-on-interposer structure 1336 coupled to the first face 1340 of the circuit board 1302 by example coupling components 1316. The coupling components 1316 may electrically and mechanically couple the package-on-interposer structure 1336 to the circuit board 1302, and may include solder balls (as shown in FIG. 13), male and female portions of a socket, an adhesive, an underfill material, and/or any other suitable electrical, chemical, and/or mechanical coupling structure.

The package-on-interposer structure 1336 may include an example IC package 1320 coupled to an example interposer 1304 by example coupling components 1318. The coupling components 1318 may take any suitable form for the application, such as the forms discussed above with reference to the coupling components 1316. Although a single IC package 1320 is shown in FIG. 13, multiple IC packages may be coupled to the interposer 1304. Additionally or alternatively, in some examples, additional interposers may be coupled to the interposer 1304. The interposer 1304 may provide an intervening substrate used to bridge the circuit board 1302 and the IC package 1320. The IC package 1320 may be or include, for example, a die (the die 1102 of FIG. 11), an IC device (e.g., the IC device 1200 of FIG. 12), and/or any other suitable component(s). Generally, the interposer 1304 may spread a connection to a wider pitch or reroute a connection to a different connection. For example, the interposer 1304 may couple the IC package 1320 (e.g., a die) to a set of BGA conductive contacts of the coupling components 1316 for coupling to the circuit board 1302. In the example illustrated in FIG. 13, the IC package 1320 and the circuit board 1302 are attached to opposing sides of the interposer 1304. In other examples, the IC package 1320 and the circuit board 1302 may be attached to a same side of the interposer 1304. In some examples, three or more components may be interconnected by way of the interposer 1304.

In some examples, the interposer 1304 may be formed as a PCB, including multiple metal layers separated from one another by layers of dielectric material and interconnected by electrically conductive vias. In some examples, the interposer 1304 may be formed of an epoxy resin, a fiberglass-reinforced epoxy resin, an epoxy resin with inorganic fillers, a ceramic material, or a polymer material such as polyimide. In some examples, the interposer 1304 may be formed of alternate rigid or flexible materials that may include the same materials described above for use in a semiconductor substrate, such as silicon, germanium, and other group III-V and group IV materials. The interposer 1304 may include example metal interconnects 1308 and example vias 1310, including but not limited to example through-silicon vias (TSVs) 1306. The interposer 1304 may further include example embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

The IC device assembly 1300 may include an example IC package 1324 coupled to the first face 1340 of the circuit board 1302 by example coupling components 1322. The coupling components 1322 may take the form of any of the examples discussed above with reference to the coupling components 1316, and the IC package 1324 may take the form of any of the examples discussed above with reference to the IC package 1320.

The IC device assembly 1300 illustrated in FIG. 13 includes an example package-on-package structure 1334 coupled to the second face 1342 of the circuit board 1302 by coupling components 1328. The package-on-package structure 1334 may include a first example IC package 1326 and a second example IC package 1332 coupled together by example coupling components 1330 such that the first IC package 1326 is disposed between the circuit board 1302 and the second IC package 1332. The coupling components 1328, 1330 may take the form of any of the examples of the coupling components 1316 discussed above, and the IC packages 1326, 1332 may take the form of any of the examples of the IC package 1320 discussed above.

FIG. 14 is a block diagram of an example electrical device 1400 that may include one or more of the example IC packages 100, 900, 1000. For example, any suitable ones of the components of the electrical device 1400 may include one or more of the device assemblies 1300, IC devices 1200, or dies 1102 disclosed herein, and may be arranged in the example IC packages 100, 900, 1000. A number of components are illustrated in FIG. 14 as included in the electrical device 1400, but any one or more of these components may be omitted or duplicated, as suitable for the application. In some examples, some or all of the components included in the electrical device 1400 may be attached to one or more motherboards. In some examples, some or all of these components are fabricated onto a single system-on-a-chip (SoC) die.

Additionally, in some examples, the electrical device 1400 may not include one or more of the components illustrated in FIG. 14, but the electrical device 1400 may include interface circuitry for coupling to the one or more components. For example, the electrical device 1400 may not include an example display 1406, but may include display interface circuitry (e.g., a connector and driver circuitry) to which the display 1406 may be coupled. In some examples, the electrical device 1400 may not include an example audio input device 1418 (e.g., microphone) or an example audio output device 1408 (e.g., a speaker, a headset, earbuds, etc.), but may include audio input or output device interface circuitry (e.g., connectors and supporting circuitry) to which the audio input device 1418 or the audio output device 1408 may be coupled.

The electrical device 1400 may include example programmable or processor circuitry 1402 (e.g., one or more processing devices). The processor circuitry 1402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 1400 may include an example memory 1404, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1404 may include memory that shares a die with the processor circuitry 1402. This memory may be used as cache memory and may include embedded dynamic random access memory (eDRAM) or spin transfer torque magnetic random access memory (STT-MRAM).

In some examples, the electrical device 1400 may include an example communication chip 1412 (e.g., one or more communication chips). For example, the communication chip 1412 may be configured for managing wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1412 may operate in accordance with other wireless protocols in other examples. The electrical device 1400 may include an example antenna 1422 to facilitate wireless communications and/or to receive other wireless communications (such as AM or FM radio transmissions).

In some examples, the communication chip 1412 may manage wired communications, such as electrical, optical, or any other suitable communication protocols (e.g., the Ethernet). As noted above, the communication chip 1412 may include multiple communication chips. For instance, a first communication chip 1412 may be dedicated to shorter-range wireless communications such as Wi-Fi or Bluetooth, and a second communication chip 1412 may be dedicated to longer-range wireless communications such as global positioning system (GPS), EDGE, GPRS, CDMA, WiMAX, LTE, EV-DO, or others. In some examples, a first communication chip 1412 may be dedicated to wireless communications, and a second communication chip 1412 may be dedicated to wired communications.

The electrical device 1400 may include example battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include the display 1406 (or corresponding interface circuitry, as discussed above). The display 1406 may include any visual indicators, such as a heads-up display, a computer monitor, a projector, a touchscreen display, a liquid crystal display (LCD), a light-emitting diode display, or a flat panel display.

The electrical device 1400 may include the audio output device 1408 (or corresponding interface circuitry, as discussed above). The audio output device 1408 may include any device that generates an audible indicator, such as speakers, headsets, or earbuds.

The electrical device 1400 may include the audio input device 1418 (or corresponding interface circuitry, as discussed above). The audio input device 1418 may include any device that generates a signal representative of a sound, such as microphones, microphone arrays, or digital instruments (e.g., instruments having a musical instrument digital interface (MIDI) output).

The electrical device 1400 may include example GPS circuitry 1416. The GPS circuitry 1416 may be in communication with a satellite-based system and may receive a location of the electrical device 1400, as known in the art.

The electrical device 1400 may include any other example output device 1410 (or corresponding interface circuitry, as discussed above). Examples of the other output device 1410 may include an audio codec, a video codec, a printer, a wired or wireless transmitter for providing information to other devices, and/or an additional storage device.

The electrical device 1400 may include any other example input device 1420 (or corresponding interface circuitry, as discussed above). Examples of the other input device 1420 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 1400 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 1400 may be any other electronic device that processes data.

From the foregoing, it will be appreciated that example systems, apparatus, articles of manufacture, and methods have been disclosed that enable IC packages that include capacitors fabricated at relatively high temperatures (e.g., above the BEOL thermal limit) to improve the capacitance density of the capacitors based on the capacitor insulator material having a higher dielectric constant than is possible for capacitors fabricated at temperatures constrained by the BEOL thermal limit. Examples disclosed herein are achieved by fabricating the capacitors on a separate substrate to the substrate on which transistors in a semiconductor die are fabricated and then bonding the separate substrates (e.g., semiconductor substrates, wafers, etc.) to assemble an example IC package with an example capacitor. As such, examples disclosed herein include a monolithic wafer including an example capacitor.

Example 1 includes an apparatus comprising a semiconductor substrate, a metal layer coupled to the semiconductor substrate, a dielectric layer coupled to the metal layer, the dielectric layer including a capacitor disposed therein, and an interface layer positioned between the metal layer and the dielectric layer, the interface layer in contact with the dielectric layer and in contact with the metal layer.

Example 2 includes the apparatus of example 1, wherein the capacitor includes a dielectric material separating a first electrode from a second electrode, the dielectric material having at least one of a perovskite crystal structure or a fluorite crystal structure.

Example 3 includes the apparatus of example 1, wherein the capacitor includes a dielectric material separating a first electrode from a second electrode, the dielectric material having a dielectric constant of at least 90.

Example 4 includes the apparatus of example 1, wherein the semiconductor substrate, the metal layer, the dielectric layer, and the interface layer correspond to portions of a semiconductor die.

Example 5 includes the apparatus of example 1, wherein the dielectric layer is a first dielectric layer and the capacitor is a first capacitor, further including a second dielectric layer positioned on an opposite side of the first dielectric layer than the interface layer, the second dielectric layer including a second capacitor.

Example 6 includes the apparatus of example 1, further including a first metal pad positioned in the interface layer, and a second metal pad positioned in the dielectric layer, the first metal pad in contact with the second metal pad.

Example 7 includes the apparatus of example 1, wherein the capacitor is a trench capacitor including first and second electrodes extending into a trench extending between first and second surfaces of the dielectric layer, the first surface adjacent to the interface layer, the first electrode having a first terminal, the second electrode having a second terminal, the first and second terminals closer to the first surface of the dielectric layer than the first and second terminals are to the second surface of the dielectric layer.

Example 8 includes the apparatus of example 7, wherein the trench has a tapered profile with a first width proximate the first surface of the dielectric layer and a second width proximate the second surface of the dielectric layer, the first width greater than the second width.

Example 9 includes the apparatus of example 1, wherein the capacitor is a planar capacitor including a first electrode, a second electrode, and a dielectric material separating the first electrode and the second electrode, a first portion of the first electrode extending adjacent to a first surface of the dielectric layer and a second portion of the first electrode is to extend from the first portion towards a second surface of the dielectric layer, the first surface opposite the second surface, the first surface facing toward the interface layer.

Example 10 includes the apparatus of example 9, wherein the first portion of the first electrode is closer to the interface layer than the second electrode is to the interface layer.

Example 11 includes the apparatus of example 10, wherein the second electrode and the first portion of the first electrode are substantially parallel to the first surface.

Example 12 includes an apparatus comprising a semiconductor die, a package substrate supporting the semiconductor die, a capacitor within a layer of dielectric material, the layer of dielectric material positioned between the semiconductor die and the package substrate, and an interface layer separating the dielectric material and a metal layer coupled to the package substrate, the interface layer in contact with the dielectric material.

Example 13 includes the apparatus of example 12, wherein the dielectric material is a first dielectric material and the capacitor is a metal-insulator-metal (MIM) capacitor, wherein the MIM capacitor includes a first metal plate and a second metal plate separated by a second dielectric material, a first portion of the first metal plate coplanar with the second metal plate, a first segment of the second dielectric material separating the first portion of the first metal plate and a first surface of the second metal plate, a second segment of the second dielectric material extending along a second surface of the second metal plate, the second surface of the second metal plate facing the interface layer, the second segment of the second dielectric material separating the second surface of second metal plate from a second portion of the first metal plate.

Example 14 includes the apparatus of example 12, wherein the dielectric material is a first dielectric material and the capacitor is a trench capacitor, the trench capacitor including a first electrode and a second electrode extending into a trench, the first and second electrodes separated by a second dielectric material, a distance between side walls of the trench reduces along the trench in a direction away from the interface layer.

Example 15 includes the apparatus of example 12, wherein the semiconductor die is a first semiconductor die, and the metal layer is within a second semiconductor die, the layer of dielectric material positioned between the first and second semiconductor dies, the layer of dielectric material to be external to and wider than the second semiconductor die.

Example 16 includes a method comprising providing a metal layer on a first semiconductor substrate, the first semiconductor substrate supporting transistors, the transistors between the first semiconductor substrate and the metal layer, fabricating a capacitor in a dielectric layer on a second semiconductor substrate distinct from the first semiconductor substrate, and mounting the second semiconductor substrate to the first semiconductor substrate, both the metal layer and the dielectric layer containing the capacitor to be between the first and second semiconductor substrates.

Example 17 includes the method of example 16, further including adding an interface layer between the metal layer and the dielectric layer to facilitate the mounting of the second semiconductor substrate to the first semiconductor substrate.

Example 18 includes the method of example 17, further including providing a first metal pad in the interface layer, and providing a second metal pad in the dielectric layer, the first and second metal pads to facilitate hybrid bonding between the interface layer and the dielectric layer.

Example 19 includes the method of example 17, further including detaching the second semiconductor substrate from the dielectric layer after the second semiconductor substrate is mounted to the first semiconductor substrate.

Example 20 includes the method of example 17, wherein the dielectric layer is a first dielectric layer and the capacitor is a first capacitor, further including fabricating a second capacitor in a second dielectric layer on a third semiconductor substrate distinct from both the first semiconductor substrate and the second semiconductor substrate, and mounting the third semiconductor substrate to the first semiconductor substrate after removal the second semiconductor substrate from the first dielectric layer, both the metal layer and the second dielectric layer containing the second capacitor to be between the first and third semiconductor substrates.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a semiconductor substrate;
a metal layer coupled to the semiconductor substrate;
a dielectric layer coupled to the metal layer, the dielectric layer including a capacitor disposed therein; and
an interface layer positioned between the metal layer and the dielectric layer, the interface layer in contact with the dielectric layer and in contact with the metal layer.

2. The apparatus of claim 1, wherein the capacitor includes a dielectric material separating a first electrode from a second electrode, the dielectric material having at least one of a perovskite crystal structure or a fluorite crystal structure.

3. The apparatus of claim 1, wherein the capacitor includes a dielectric material separating a first electrode from a second electrode, the dielectric material having a dielectric constant of at least 90.

4. The apparatus of claim 1, wherein the semiconductor substrate, the metal layer, the dielectric layer, and the interface layer correspond to portions of a semiconductor die.

5. The apparatus of claim 1, wherein the dielectric layer is a first dielectric layer and the capacitor is a first capacitor, further including a second dielectric layer positioned on an opposite side of the first dielectric layer than the interface layer, the second dielectric layer including a second capacitor.

6. The apparatus of claim 1, further including:
a first metal pad positioned in the interface layer; and
a second metal pad positioned in the dielectric layer, the first metal pad in contact with the second metal pad.

7. The apparatus of claim 1, wherein the capacitor is a trench capacitor including first and second electrodes extending into a trench extending between first and second surfaces of the dielectric layer, the first surface adjacent to the interface layer, the first electrode having a first terminal, the second electrode having a second terminal, the first and second terminals closer to the first surface of the dielectric layer than the first and second terminals are to the second surface of the dielectric layer.

8. The apparatus of claim 7, wherein the trench has a tapered profile with a first width proximate the first surface of the dielectric layer and a second width proximate the second surface of the dielectric layer, the first width greater than the second width.

9. The apparatus of claim 1, wherein the capacitor is a planar capacitor including a first electrode, a second electrode, and a dielectric material separating the first electrode and the second electrode, a first portion of the first electrode extending adjacent to a first surface of the dielectric layer and a second portion of the first electrode is to extend from the first portion towards a second surface of the dielectric layer, the first surface opposite the second surface, the first surface facing toward the interface layer.

10. The apparatus of claim 9, wherein the first portion of the first electrode is closer to the interface layer than the second electrode is to the interface layer.

11. The apparatus of claim 10, wherein the second electrode and the first portion of the first electrode are substantially parallel to the first surface.

12. An apparatus comprising:
a semiconductor die;
a package substrate supporting the semiconductor die;
a capacitor within a layer of dielectric material, the layer of dielectric material positioned between the semiconductor die and the package substrate; and
an interface layer separating the dielectric material and a metal layer coupled to the package substrate, the interface layer in contact with the dielectric material.

13. The apparatus of claim 12, wherein the dielectric material is a first dielectric material and the capacitor is a metal-insulator-metal (MIM) capacitor, wherein the MIM capacitor includes a first metal plate and a second metal plate separated by a second dielectric material, a first portion of the first metal plate coplanar with the second metal plate, a first segment of the second dielectric material separating the first portion of the first metal plate and a first surface of the second metal plate, a second segment of the second dielectric material extending along a second surface of the second metal plate, the second surface of the second metal plate facing the interface layer, the second segment of the second dielectric material separating the second surface of second metal plate from a second portion of the first metal plate.

14. The apparatus of claim 12, wherein the dielectric material is a first dielectric material and the capacitor is a trench capacitor, the trench capacitor including a first electrode and a second electrode extending into a trench, the first and second electrodes separated by a second dielectric material, a distance between side walls of the trench reduces along the trench in a direction away from the interface layer.

15. The apparatus of claim 12, wherein the semiconductor die is a first semiconductor die, and the metal layer is within a second semiconductor die, the layer of dielectric material positioned between the first and second semiconductor dies, the layer of dielectric material to be external to and wider than the second semiconductor die.

16. A method comprising:
providing a metal layer on a first semiconductor substrate, the first semiconductor substrate supporting transistors, the transistors between the first semiconductor substrate and the metal layer;
fabricating a capacitor in a dielectric layer on a second semiconductor substrate distinct from the first semiconductor substrate; and
mounting the second semiconductor substrate to the first semiconductor substrate, both the metal layer and the dielectric layer containing the capacitor to be between the first and second semiconductor substrates.

17. The method of claim 16, further including adding an interface layer between the metal layer and the dielectric layer to facilitate the mounting of the second semiconductor substrate to the first semiconductor substrate.

18. The method of claim 17, further including:
providing a first metal pad in the interface layer; and
providing a second metal pad in the dielectric layer, the first and second metal pads to facilitate hybrid bonding between the interface layer and the dielectric layer.

19. The method of claim 17, further including detaching the second semiconductor substrate from the dielectric layer after the second semiconductor substrate is mounted to the first semiconductor substrate.

20. The method of claim 17, wherein the dielectric layer is a first dielectric layer and the capacitor is a first capacitor, further including:
fabricating a second capacitor in a second dielectric layer on a third semiconductor substrate distinct from both the first semiconductor substrate and the second semiconductor substrate; and
mounting the third semiconductor substrate to the first semiconductor substrate after removal the second semiconductor substrate from the first dielectric layer, both the metal layer and the second dielectric layer containing the second capacitor to be between the first and third semiconductor substrates.
